(19) United States
(12) Patent Application Publication
(10) Pub. No.: US 2026/0009848 A1
(43) Pub. Date: Jan. 8, 2026

(54) RESET TEST SYSTEM AND SYSTEM-ON-CHIP INCLUDING THE SAME

(71) Applicant: ITDA SEMICONDUCTOR CO., LTD., Hwaseong-si (KR)

(72) Inventors: Ahchan KIM, Hwaseong-si (KR); Hoyeon JEON, Seongnam-si (KR); Ingyu KIM, Hwaseong-si (KR); Jaesung LEE, Seoul (KR)

(73) Assignee: ITDA SEMICONDUCTOR CO., LTD., Hwaseong-si (KR)

(21) Appl. No.: 19/255,653

(22) Filed: Jun. 30, 2025

(30) Foreign Application Priority Data
Jul. 2, 2024 (KR) 10-2024-0086592
Jan. 16, 2025 (KR) 10-2025-0006929

(51) Int. Cl. G01R 31/3185

(52) U.S. Cl. CPC G01R 31/318544; G01R 31/318594; G01R 31/318597

(57) ABSTRACT

A reset test system and a system-on-chip, which enable a test reset to be transmitted through the same path as a functional reset in a reset test mode. The reset test system includes a scan test controller configured to generate a scan test enable signal, a scan reset control signal, and a scan reset deactivation signal; a target reset test controller configured to generate a target reset test mode signal and target reset test data; a leading target reset controller configured to synchronize a leading reset input to a functional clock in a functional mode and to output the target reset test data as a leading reset output in a scan test mode; and a following target reset controller configured to receive the leading reset output as a following reset input, synchronize it to the functional clock in the functional mode, and output the target reset test data.

### STATEMENT REGARDING GOVERNMENT SPONSORED RESEARCH OR DEVELOPMENT

This invention was made with support from the Ministry of SMEs and Startups through a grant funded by the Korea Technology and Information Promotion Agency for SMEs (TIPA), under Project Unique Number 1425182152 and Project Number RS-2023-00302523, within the Startup Growth Technology Development (R&D) program. The project titled “Low-Code Based Low-Power Semiconductor Solution” was executed by ITDA Semiconductor Co., Ltd., with the research period spanning from Jul. 1, 2023, to Jun. 30, 2026. However, no rights in the invention are held by the government of the Republic of Korea.

### CROSS-REFERENCE TO RELATED APPLICATION

This application claims the benefit of and priority to Korean Patent Application Nos. 10-2024-0086592, filed on Jul. 2, 2024, and 10-2025-0006929, filed on Jan. 16, 2025, the entire disclosures of which are incorporated herein by reference in their entirety.

### TECHNICAL FIELD

The present disclosure relates to a reset test system and a system-on-chip including the same, and more particularly, to a reset test system that allows a test reset to be transmitted through the same path as a functional reset path in a reset test mode, and to a system-on-chip including the same.

### BACKGROUND

A system-on-chip (SoC) refers to a technology that integrates various functional blocks, such as a central processing unit (CPU), memory, interface, digital signal processing circuit, and analog signal processing circuit, into a single semiconductor integrated circuit for implementing a computer system or other electronic systems, or to an integrated circuit (IC) fabricated based on the technology. The SoC has evolved into more complex systems that include various functional blocks, such as processors, multimedia, graphics, interfaces, and security. The SoC may be driven in a test mode to detect defects during the design and manufacturing process and to verify that the SoC operates properly, and may be driven in a functional mode when passing a test and operating normally.

FIG. 1 is a block diagram illustrating a typical system-on-chip (SoC) device.

The SoC device may include an input/output pad 110, a clock management unit (CMU) 120, a power management unit (PMU) 130, a reset management unit (RMU) 140, and one or more intellectual property (IP) blocks 150 and 160. When operating in a functional mode, the CMU 120 may generate a first and a second functional clock (CLK1, CLK2) respectively provided to the first and second IP blocks 150 and 160.

Each of the first and second IP blocks 150 and 160 is connected to a system bus and may communicate with the other through the system bus. Each of the first and second IP blocks 150, 160 may be a processor, a graphics processor, a memory controller, an input and output interface block.

The CMU 120 includes a plurality of clock components, and may provide a first functional clock (CLK1) to the first IP block 150 when the first IP block 150 operates, and may provide a second functional clock (CLK2) to the second IP block 160 when the second IP block 160 operates.

The PMU 130 includes a plurality of power components and controls the power supplied to the SoC device. For example, when the SoC device enters a standby mode, the PMU 130 provides a power sequence (PWR1, PWR2) for powering down the first and second IP blocks 150 and 160, so that the power supplied to the IP blocks is cut off. In addition, when the SoC device operates in an operation mode, the PMU 130 provides a power sequence (PWR1, PWR2) for powering up the first and second IP blocks 150 and 160, so that power is supplied respectively to the IP blocks.

The RMU 140 detects a reset mode of the SoC device and transmits reset signals (RST1, RST2) to the first and second IP blocks 150 and 160 through the PMU 130 so that the hardware can be initialized. In addition, reset signals generated by the RMU 140 may also be transmitted to the PMU 130 and the CMU 120, such that when the IP blocks 150 and 160 are reset, the power components of the PMU 130 and the clock components of the CMU 120 are also reset.

The reset mode may be used to initialize a specific part of the system or to return the system to a specific state. The reset mode may include a power-on reset (POR_reset), a pin-activated reset (PAD_reset), a software reset, a watchdog reset, a brown-out reset (BOR_reset), a cold reset, and a warm reset.

A power-on reset (POR_reset) is a reset that automatically occurs when power is first supplied to the system. This reset is intended to ensure stable booting by initializing all hardware modules, registers, flip-flops, and internal memory when the system is first started.

A pin-activated reset (PAD_reset) is a reset that is triggered when an external reset pin is pressed, typically when a user manually initializes the system. This reset initializes important registers and internal states, but its reset scope may be more limited than that of a power-on reset.

A software reset is a reset triggered by a software command. It may be executed when the system encounters a specific software condition or an error, and mainly initializes registers associated with the CPU and specific hardware modules.

A watchdog reset refers to a reset that automatically occurs when the system fails to operate normally within an expected time, and is used to recover the system in the event of a software error or infinite loop. It is triggered when the watchdog timer times out, and may reset the entire system or a portion thereof.

The brown out reset (BOR_reset) is a reset that occurs when the power supply becomes unstable or drops below a certain threshold, is used to protect the system when the power supply is unstable, and allows the system to remain in a reset state until the power is stably restored.

The cold reset is a reset that occurs when the power is turned off and then turned on again, and all system states may be initialized. A power on reset and a pin-activated reset are examples of cold resets.

The warm reset is a reset that occurs while the power is maintained, in which only part of the system is initialized. In this case, only the CPU and some hardware modules are reset, while memory may be retained.

In other words, depending on the type of reset, either all components and IP blocks of the SoC device may be reset, or only a portion thereof, such as some IP blocks or components, may be reset.

During operation in the functional mode, it may be necessary to initialize the components or IP blocks of the SoC device in order to maintain system reliability, stability, and security in cases such as system rebooting, recovering from errors, updating firmware or software, responding to power instability, resolving clock and timing issues, or coping with external changes.

The RMU 140 may include a functional reset generation unit that generates and distributes a reset signal in a functional mode. The functional reset generation unit may receive a trigger from various reset sources (power-on, external reset pin, watchdog timer, and software command) and generate a reset signal to distribute to components within the SoC device so that the corresponding components are reset. The reset signal may include a power on reset signal, a pin activated reset signal, a cold reset signal, a soft reset signal, and a specific IP block reset signal.

The path along which the reset signal is transmitted when the SoC operates in a functional mode may be referred to as a functional reset path.

FIG. 2 is a diagram illustrating a functional reset path through which a reset signal is transmitted to an arbitrary reset target in a functional mode.

A functional reset generation unit 210 receives a trigger from various reset sources and generates a reset signal. A clock management unit 220 generates a functional clock (CLK) and transmits it to a target 240. Depending on the target 240, the functional clock (CLK) may be a high-speed clock or a low-speed clock, and the target 240 may be one of an IP block, power components of the PMU, clock components of the CMU, and internal logic circuits of each unit.

The reset signal may be transmitted to the target 240 through a functional reset path 250. The functional reset path 250 may include at least one component. Depending on the reset source, the functional reset generation unit 210 may transmit a reset signal to at least one of the power components of the PMU, the clock components of the CMU, the IP blocks, or the internal logic circuits of each unit.

For example, in the case where the reset source is a cold reset such as a power-on and an external reset pin activation, the functional reset generation unit 210 generates a cold reset signal, and the cold reset signal may be distributed to all IP blocks, all components of the system, and the logic circuits, and all components of the system may include all power components of the PMU and all clock components of the CMU. In this connection, the target 240 may be one of all components and logic circuits of the SoC device. In the case where the reset source is a warm reset or software reset in which only some components of the SoC device are reset, the functional reset generation unit 210 provides a reset signal only to some components or logic circuits, and in this case, the target 240 may be one of the said components or logic circuits.

The reset signal generated in the functional reset generation unit 210 is transmitted to a synchronizer 230 along the functional reset path 250, and the synchronizer 230 synchronizes the reset signal with the functional clock (CLK) supplied to the target 240 and outputs it to the target 240. In other words, the reset signal synchronized with the functional clock (CLK) of the target 240 is provided to the target 240, and when the reset signal is input to the target 240, the target 240 is initialized.

As such, the functional reset generation unit 210 generates a reset signal while the SoC device is operating normally, and transmits the reset signal to each IP block or each component of the system through each functional reset path.

In another aspect, a logic test may be performed to functionally verify and detect defects in the digital circuits configuring the SoC. The logic test is a process of verifying the logic path and state of a digital circuit, and may include a scan test, a built-in self-test (BIST), a pattern-based test, and a reset test. In the reset test, a test may be performed to check whether the reset signal operates properly and whether the state of the digital circuit is initialized after the reset.

As described above, in a functional mode, the reset signal generated by the functional reset generation unit 210 may be transmitted to each of the plurality of components and IP blocks that configure the system through respective functional reset paths. That is, since functional reset paths are formed for each of the components and IP blocks, it is desirable to test all the functional reset paths of the respective components and IP blocks during the reset test in the logic test.

However, the current design-for-test (DFT) of the SoC device is configured to perform the reset test only on the IP blocks, rather than testing the functional reset paths for all components of the system.

FIG. 3 is a block diagram illustrating a conventional reset test system of an IP block.

The conventional reset test system includes a test reset generation unit 310 that outputs a test reset in a test mode, and a test multiplexer (Test MUX) 320 that selectively provides either a test reset provided from the test reset generation unit 310 or a functional reset generated by the functional reset generation unit 210 and transmitted through the functional reset path 250 to the IP block 241.

The test multiplexer 320 provides a test reset, which is input from the test reset generation unit 310 in the test mode, to the IP block 241, and provides a functional reset, which is generated by the functional reset generation unit 210 and transmitted through the functional reset path 250, to the IP block 241 in the functional mode.

This conventional reset test system is disposed immediately upstream of the IP block 241 and provides a test reset to the IP block 241.

However, in the case of conventional reset tests, since the path through which the functional reset is transmitted to the IP block in the functional mode of the SoC device and the path through which the test reset is transmitted to the IP block in the test mode are different from each other, tests for all the functional reset paths are not performed, which reduces test coverage.

In addition, since reset tests for some components of the SoC device or internal logic circuits of a unit may not be performed, test coverage is reduced. In other words, although the synchronizer is located on the functional reset path, a reset test for the synchronizer cannot be executed because the test reset is not transmitted to the synchronizer during the reset test.

### SUMMARY

An aspect of the present disclosure is directed to providing a reset test system that enables a test reset to be transmitted through the same path as a functional reset path in a reset test mode, and to enabling a reset function to be tested for each component and IP block that configures a system-on-chip during the reset test, as well as to providing a system-on-chip including the same.

A reset test system according to an embodiment of the present disclosure includes: a scan test controller configured to generate a scan test enable signal (ltest_en) indicating whether a scan test mode is activated, a scan reset control signal (ltest_reset) configured to control a reset in the scan test mode, and a scan reset deactivation signal (ltest_rstdisable) configured to deactivate the reset in the scan test mode; a target reset test controller configured to generate a target reset test mode signal (TEST_MODE) indicating whether a target is in a test mode and target reset test data (TEST_MODE_RESET); a leading target reset controller configured to receive the scan test enable signal (ltest_en), the scan reset control signal (ltest_reset), the scan reset deactivation signal (ltest_rstdisable), the target reset test mode signal (TEST_MODE), the target reset test data (TEST_MODE_RESET), and a leading reset input, configured to synchronize the leading reset input to a functional clock of the target and output the synchronized signal as a leading reset output in a functional mode, and configured to output the target reset test data (TEST_MODE_RESET) as the leading reset output when the reset is activated in the scan test mode; and a following target reset controller configured to receive the scan reset deactivation signal (ltest_rstdisable), the target reset test mode signal (TEST_MODE), the target reset test data (TEST_MODE_RESET), and the leading reset output as a following reset input, configured to synchronize the following reset input to the functional clock of the target and output the synchronized signal as a following reset output in the functional mode, and configured to output the target reset test data (TEST_MODE_RESET) as the following reset output when the reset is activated in the scan test mode.

Preferably, the leading target reset controller includes a leading synchronizer configured to synchronize the leading reset input to a functional clock of the target; the following target reset controller comprises a following synchronizer configured to synchronize the following reset input to the functional clock of the target; and the leading synchronizer and the following synchronizer are configured to be reset when the reset is activated in the scan test mode.

Preferably, the target reset test controller is a built-in controller based on the IEEE1687 standard.

Preferably, the target reset test controller is disposed corresponding to each reset domain.

Preferably, the target reset test controller includes a test mode test data register (TDR) configured to output the target reset test mode signal (TEST_MODE) indicating whether a reset test mode of the target is activated or deactivated; and a test control test data register (TDR) configured to output the target reset test data (TEST_MODE_RESET) in response to the activation of the reset test mode of the target.

Preferably, the test mode test data register (TDR) and the test control test data register (TDR) are configured via an Internal Joint Test Action Group (IJTAG) interface.

Preferably, the leading target reset controller includes: a first test multiplexer in which the scan reset control signal (ltest_reset) and the leading reset input are input to each input terminal, and the scan test enable signal (ltest_en) is input to a selection terminal and outputs one of the scan reset control signal (ltest_reset) and the leading reset input according to the scan test enable signal (ltest_en); and a first OR operator that performs an OR operation on an output of the first test multiplexer and the scan reset deactivation signal (ltest_rstdisable) and outputs a result to the leading synchronizer.

Preferably, the leading target reset controller further includes: a second OR operator that performs an OR operation on an output of the leading synchronizer and the scan reset deactivation signal (ltest_rstdisable); and a second test multiplexer in which an output of the second OR operator and the target reset test data (TEST_MODE_RESET) are input to each input terminal, and the target reset test mode signal (TEST_MODE) is input to the selection terminal and outputs one of the output of the second OR operator and the target reset test data (TEST_MODE_RESET) according to the target reset test mode signal (TEST_MODE).

Preferably, the following target reset controller includes: a first test multiplexer in which a selection terminal and one input terminal are each fixed to a zero level, and the leading reset input is input to another input terminal to output the leading reset input; and a first OR operator that performs an OR operation on the leading reset input output from the first test multiplexer and the scan reset deactivation signal (ltest_rstdisable) and outputs a result to the following synchronizer.

Preferably, the following target reset controller further includes: a second OR operator that performs an OR operation on an output of the following synchronizer and the scan reset deactivation signal (ltest_rstdisable); and a second test multiplexer in which an output of the second OR operator and the target reset test data (TEST_MODE_RESET) are input to each input terminal, and the target reset test mode signal (TEST_MODE) is input to the selection terminal and outputs one of the output of the second OR operator and the target reset test data (TEST_MODE_RESET) according to the target reset test mode signal (TEST_MODE).

A system-on-chip of the present disclosure includes a reset test system. The reset test system includes: a scan test controller configured to generate a scan test enable signal (ltest_en) indicating whether a scan test mode is activated, a scan reset control signal (ltest_reset) configured to control a reset in the scan test mode, and a scan reset deactivation signal (ltest_rstdisable) configured to deactivate the reset in the scan test mode; a target reset test controller configured to generate a target reset test mode signal (TEST_MODE) indicating whether a target is in a test mode and target reset test data (TEST_MODE_RESET); a leading target reset controller configured to receive the scan test enable signal (ltest_en), the scan reset control signal (ltest_reset), the scan reset deactivation signal (ltest_rstdisable), the target reset test mode signal (TEST_MODE), the target reset test data (TEST_MODE_RESET), and a leading reset input, configured to synchronize the leading reset input to a functional clock of the target and output the synchronized signal as a leading reset output in a functional mode, and configured to output the target reset test data (TEST_MODE_RESET) as the leading reset output when the reset is activated in the scan test mode; and a following target reset controller configured to receive the scan reset deactivation signal (ltest_rstdisable), the target reset test mode signal (TEST_MODE), the target reset test data (TEST_MODE_RESET), and the leading reset output as a following reset input, configured to synchronize the following reset input to the functional clock of the target and output the synchronized signal as a following reset output in the functional mode, and configured to output the target reset test data (TEST_MODE_RESET) as the following reset output when the reset is activated in the scan test mode.

Preferably, the leading target reset controller includes a leading synchronizer configured to synchronize the leading reset input to a functional clock of the target; the following target reset controller comprises a following synchronizer configured to synchronize the following reset input to the functional clock of the target; and the leading synchronizer and the following synchronizer are configured to be reset when the reset is activated in the scan test mode.

Preferably, the target reset test controller is a built-in controller based on the IEEE1687 standard.

Preferably, the target reset test controller is disposed corresponding to each reset domain.

Preferably, the target reset test controller includes a test mode test data register (TDR) configured to output the target reset test mode signal (TEST_MODE) indicating whether a reset test mode of the target is activated or deactivated; and a test control test data register (TDR) configured to output the target reset test data (TEST_MODE_RESET) in response to the activation of the reset test mode of the target.

Preferably, the test mode test data register (TDR) and the test control test data register (TDR) are configured via an Internal Joint Test Action Group (IJTAG) interface.

Preferably, the leading target reset controller includes: a first test multiplexer in which the scan reset control signal (ltest_reset) and the leading reset input are input to each input terminal, and the scan test enable signal (ltest_en) is input to a selection terminal and outputs one of the scan reset control signal (ltest_reset) and the leading reset input according to the scan test enable signal (ltest_en); and a first OR operator that performs an OR operation on an output of the first test multiplexer and the scan reset deactivation signal (ltest_rstdisable) and outputs a result to the leading synchronizer.

Preferably, the leading target reset controller further includes: a second OR operator that performs an OR operation on an output of the leading synchronizer and the scan reset deactivation signal (ltest_rstdisable); and a second test multiplexer in which an output of the second OR operator and the target reset test data (TEST_MODE_RESET) are input to each input terminal, and the target reset test mode signal (TEST_MODE) is input to the selection terminal and outputs one of the output of the second OR operator and the target reset test data (TEST_MODE_RESET) according to the target reset test mode signal (TEST_MODE).

Preferably, the following target reset controller includes: a first test multiplexer in which a selection terminal and one input terminal are each fixed to a zero level, and the leading reset input is input to another input terminal to output the leading reset input; and a first OR operator that performs an OR operation on the leading reset input output from the first test multiplexer and the scan reset deactivation signal (ltest_rstdisable) and outputs a result to the following synchronizer.

Preferably, the following target reset controller further includes: a second OR operator that performs an OR operation on an output of the following synchronizer and the scan reset deactivation signal (ltest_rstdisable); and a second test multiplexer in which an output of the second OR operator and the target reset test data (TEST_MODE_RESET) are input to each input terminal, and the target reset test mode signal (TEST_MODE) is input to the selection terminal and outputs one of the output of the second OR operator and the target reset test data (TEST_MODE_RESET) according to the target reset test mode signal (TEST_MODE).

### Advantageous Effects

An embodiment of the present disclosure provides the following benefits.

Since a test reset path is formed along the same path as a functional reset path, the present disclosure allows testing whether the components configuring the functional reset path operate normally, thereby expanding test coverage.

The present disclosure can expand test coverage by allowing a reset test to be performed on a synchronizer located on the functional reset path.

The present disclosure disposes a leading target reset controller at the most upstream end of a reset domain, and allows a following target reset controller positioned downstream to operate based on a reset output of the leading target reset controller, thereby enabling testing of the reset signal connection path between the target reset controllers and expanding the test coverage.

The present disclosure can provide a test reset to each of the IP blocks and components of a system-on-chip device when the system-on-chip device operates in a test mode, thereby enabling the reset test to be reliably performed for each of the components and IP blocks.

The benefits of the present disclosure are not limited to those mentioned above, and other benefits not mentioned herein will be clearly understood by those having ordinary skill in the technical field to which the present disclosure pertains (hereinafter, “those skilled in the art”) from the following description.

### BRIEF DESCRIPTION OF THE DRAWINGS

Embodiments of the present disclosure will be described with reference to the accompanying drawings, where similar reference numerals denote similar elements. However, the embodiments are not limited thereto.

FIG. 1 is a block diagram illustrating a typical system-on-chip (SoC) device.

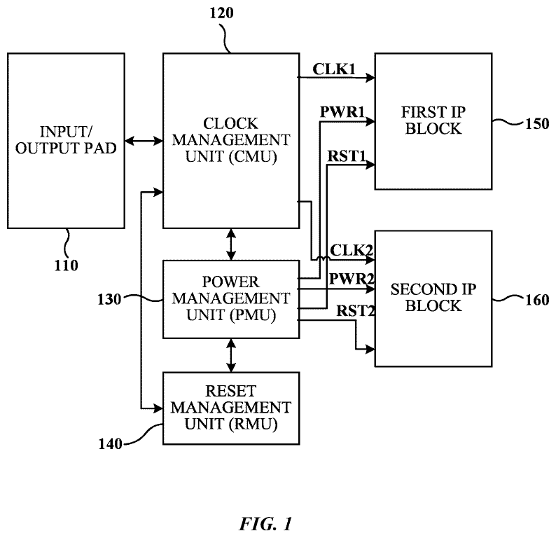

FIG. 2 is a diagram illustrating a functional reset path in which a reset signal is transmitted to an arbitrary reset target in a functional mode.

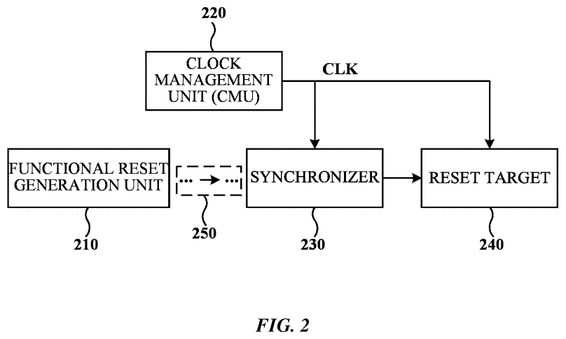

FIG. 3 is a configuration block diagram illustrating a conventional reset test system of an IP block.

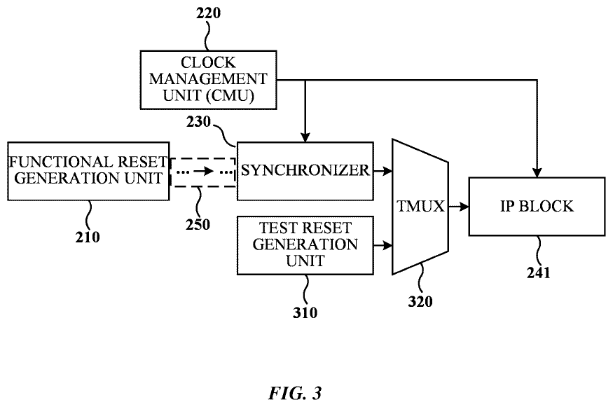

FIG. 4 is a configuration diagram illustrating a system-on-chip device including a power management cluster (PMC) to which an embodiment of the present disclosure is applied.

FIG. 5 is a configuration block diagram illustrating a reset test system applied to a reset domain including a root power manager and a domain power manager according to an embodiment of the present disclosure.

FIG. 6 is a configuration block diagram illustrating a reset test system applied to a reset domain including a second power management interface and an IP block according to an embodiment of the present disclosure.

FIG. 7 is a configuration block diagram illustrating a reset test system including a leading target reset controller according to an embodiment of the present disclosure; and

FIG. 8 is a configuration block diagram illustrating a reset test system including a following target reset controller according to an embodiment of the present disclosure.

### DETAILED DESCRIPTION

Hereinafter, specific details for the practice of the present disclosure will be described in detail with reference to the accompanying drawings. However, in the following description, detailed descriptions of well-known functions or configurations will be omitted when it may make the subject matter of the present disclosure rather unclear.

In the accompanying drawings, the same or corresponding components are assigned the same reference numerals. Further, in the following description of the embodiments, duplicate descriptions of the same or corresponding components may be omitted. However, even if descriptions of components are omitted, it is not intended that such components are not included in any embodiment.

The advantages and features of the embodiments of the present disclosure and methods of achieving the same will be apparent from the embodiments described below in connection with the accompanying drawings. However, the present disclosure is not limited to the embodiments disclosed below, and may be implemented in various different forms, and the present embodiments are merely provided to fully disclose the scope of embodiments to those skilled in the art to which the present disclosure pertains.

Unless otherwise defined, all terms (including technical and scientific terms) used herein have the same meaning as commonly understood by those skilled in the technical field to which the present disclosure pertains. It will be further understood that terms, such as those defined in commonly used dictionaries, should not be interpreted in an idealized or overly formal sense unless expressly so defined herein.

For example, the term “technique” may refer to a system, method, computer-readable instructions, module, algorithm, hardware logic, and/or an operation permitted by the context described above and throughout this document.

As used herein, the singular forms are intended to include the plural forms as well, unless the context clearly indicates the singular forms. Further, the plural forms are intended to include the singular forms as well, unless the context clearly indicates the plural forms. Further, throughout the description, when a portion is stated as including a component, it intends to mean that the portion may additionally include another component, rather than excluding the same, unless specified to the contrary.

In this present disclosure, the terms “comprising,” “having,” or the like are used to specify that features, steps, operations, elements and/or components exists, and they do not preclude the addition of one or more other features, steps, operations, elements, components, and/or combinations thereof.

In the present disclosure, when a particular component is referred to as being “coupled to,” “combined with,” “connected to,” “related to,” or as “responding to” any other component, the particular component may be directly coupled to, combined with, connected to, and/or related to, or may directly respond to the other component; however, the present disclosure is not limited to the relationship. For example, there may be one or more intermediate components between a particular component and another component. In addition, in the present disclosure, “and/or” may include one or more of the listed items or a combination of at least a portion of one or more of the listed items.

In the present disclosure, the terms such as “first” and “second” are used to distinguish a particular component from the other components, and thus the component should not be limited by those terms. For example, a “first” component may be used to indicate a component in a form similar to or the same as a “second” component.

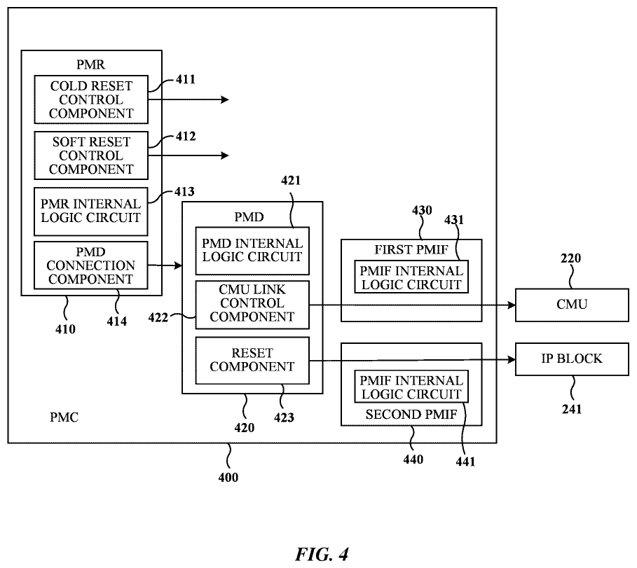

FIG. 4 is a configuration diagram illustrating a system-on-chip device including a power management cluster (PMC) to which an embodiment of the present disclosure is applied.

The system-on-chip device may include a PMC 400. The PMC 400 may be connected to at least one IP block 241 and may provide a power up/down sequence to the IP block 241. The IP block 241 may process the power up/down sequence to enter a power up state or a power down state. The system-on-chip device may include more than one PMC 400.

The PMC 400 may include at least one power management for domain (PMD) 420 that controls power of the IP block 241, a power management for root (PMR) 410 that manages the at least one PMD 420, at least one first power management interface (PMIF) 430 disposed between the at least one PMD 420 and the clock management unit 220, and at least one second power management interface (PMIF) 440 disposed between the at least one PMD 420 and the IP block 241. The clock management unit 220 may provide a functional clock to the PMR 410, the PMD 420, the first and second power management interfaces 430, 440, and the IP block 241.

The PMR 410 and the at least one PMD 420 are disposed in an always-on (AON) domain area, the first power management interface (PMIF) 430 is disposed on the side of the clock management unit 220, and the second power management interface (PMIF) 440 is disposed on the side of the IP block 241.

The PMR 410 may include a cold reset control component 411 that receives a cold reset signal and controls all components and all IP blocks of the system-on-chip device to be reset, a soft reset control component 412 that receives a soft reset signal and controls some components and some IP blocks of the system-on-chip device to be reset, a PMR internal logic circuit 413 that is a logic circuit within the PMR itself, and a PMD connection component 414 that manages a connection with the PMD. The PMD 420 may be connected to the PMR 410 via the PMD connection component 414. In the drawing, one PMD 420 is connected to the PMR 410, but a plurality of PMD may be connected via a plurality of PMD connection components.

The cold reset signal and the soft reset signal may be provided from a functional reset generation unit. The cold reset control component 411 and the soft reset control component 412 may control a register of the PMR 410 and/or a register of the PMD 420 so that logic circuits and components controlled by the registers are reset. In addition, an integrated driving circuit controlled by the PMR 410 may be further reset.

The PMD 420 may include a PMD internal logic circuit 421 which is a logic circuit within the PMD itself, a CMU link control component 422 which controls a link with the clock management unit 220, and a reset component 423 for sending a reset signal to the IP block 241.

The first power management interface 430 and the second power management interface 440 may respectively include PMIF internal logic circuits 431 and 441.

As described above, the PMR 410 and the at least one PMD 420 are physically disposed in the same AON domain area, the first power management interface 430 and the clock management unit 220 are physically disposed in the same power domain area, and the second power management interface 440 and the IP block 241 are physically disposed in the same power domain area.

In an embodiment of the present disclosure, the reset domain may be divided based on the physical power domain area. In other words, the PMR 410 and the PMD 420 may configure one reset domain, the first power management interface 430 and the clock management unit 220 may configure one reset domain, and the second power management interface 440 and the IP block 241 may configure one reset domain.

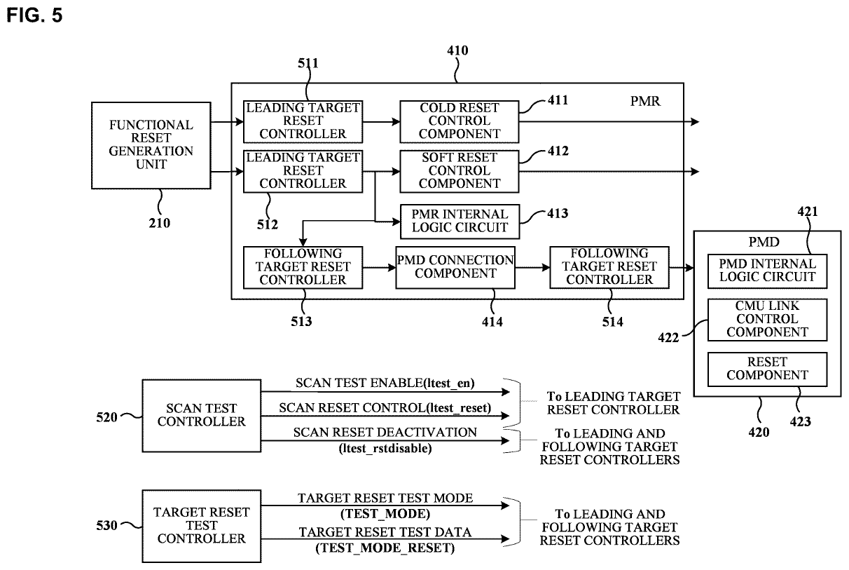

FIG. 5 is a configuration block diagram illustrating a reset test system applied to a reset domain including a root power manager and a domain power manager according to an embodiment of the present disclosure.

The reset test system may include a plurality of target reset controllers disposed at an upstream side of a target, receiving a functional reset and a functional clock of the target and selectively outputting the functional reset or a test reset synchronized to the functional clock. These target reset controllers may be disposed in a functional reset path of any target. The functional reset path of any target may include at least one target reset controller. The target reset controller includes a leading target reset controller 511, 512 positioned at the most upstream end of a functional reset path within the reset domain, and a following target reset controller 513, 514 connected downstream to the reset output of the leading target reset controller 511, 512 within the reset domain.

The target may include components 411, 412, and 414 that configure the PMR 410; the PMR internal logic circuit 413; components 422 and 423 that configure the PMD 420; and the PMD internal logic circuit 421. For example, the PMD connection component 414 may be included in the functional reset path of the PMD 420, and one leading target reset controller 512 and two following target reset controllers 513, 514 may be disposed in the functional reset path of the PMD 420.

In the present disclosure, as described above, the leading target reset controller 512, the following target reset controller 513, and the following target reset controller 514 may be connected in series. During a scan test, it is possible to test the connection between the leading target reset controller 512 and the following target reset controller 513, as well as the connection path between the following target reset controller 513 and the following target reset controller 514, thereby expanding test coverage.

The leading target reset controller 511 may have the cold reset control component 411 as a target, and may selectively output a functional reset or a test reset synchronized with the functional clock of the cold reset control component 411 to the cold reset control component 411. The leading target reset controller 512 may have the soft reset control component 412 and the PMR internal logic circuit 413 as targets, and may selectively output the functional reset or the test reset synchronized with the functional clock of the target to the targets. The following target reset controller 513 may have the PMD connection component 414 as a target, and may selectively output the functional reset or the test reset synchronized with the functional clock of the PMD connection component 414 to the PMD connection component 414. The following target reset controller 514 may have the PMD 420 as a target, and may selectively output the functional reset or the test reset synchronized with the functional clock of the PMD to the PMD 420.

The functional reset generation unit 210 may set a functional reset register, and a setting value of the register may be input as a functional reset to the leading target reset controllers 511 and 512. The reset output of the leading target reset controller 512 may be provided as a reset input to the following target reset controller 513 located downstream thereof, and the reset output of the following target reset controller 513 may be provided as a reset input to the following target reset controller 514 located further downstream.

The reset test system includes: a scan test controller 520 that outputs a scan test enable signal (ltest_en) indicating whether a scan test mode is activated, a scan reset control signal (ltest_reset) controlling reset in the scan test mode, and a scan reset deactivation signal (ltest_rstdisable) controlling the reset to be deactivated in the scan test mode; and a target reset test controller 530 that outputs a target reset test mode signal (TEST_MODE) which indicates whether the target is in a test mode, and target reset test data (TEST_MODE_RESET).

The scan test enable signal (ltest_en) and the scan reset control signal (ltest_reset) are output only to the leading target reset controller 511, 512, and the scan reset deactivation signal (ltest_rstdisable), the target reset test mode signal (TEST_MODE), and the target reset test data (TEST_MODE_RESET) are output to both the leading target reset controller 511, 512 and the following target reset controller 513, 514.

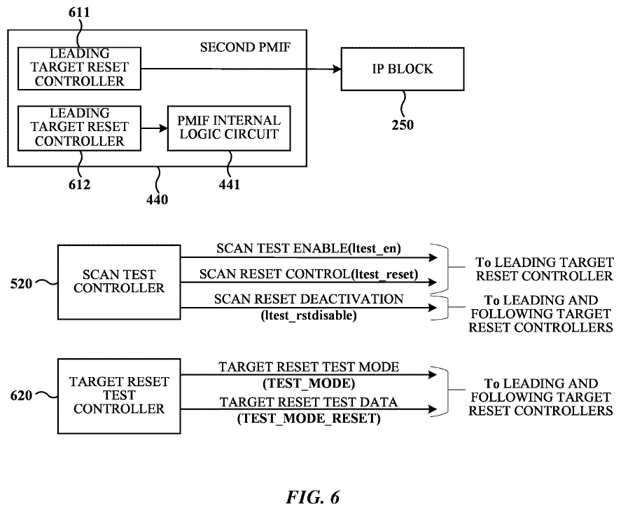

FIG. 6 is a configuration block diagram illustrating a reset test system applied to a reset domain including a second power management interface and an IP block according to an embodiment of the present disclosure.

The reset test system may include a plurality of leading target reset controllers 611 and 612, which are disposed at the upstream of a target, receive a functional reset and a functional clock of the target, and selectively output a functional reset or a test reset synchronized with the functional clock. The leading target reset controllers 611 and 612 may be disposed at the most upstream position of the functional reset path within the reset domain. Although the embodiment of FIG. 6 describes the reset test system as including only the leading target reset controllers, the present disclosure is not limited thereto and may further include one or more following target reset controllers disposed at the downstream of the leading target reset controllers. The target may include the PMIF internal logic circuit 441 and the IP block 241 of the second power management interface.

The reset test system further includes: a scan test controller 520 configured to output a scan test enable signal (ltest_en) indicating whether a scan test mode is activated, a scan reset control signal (ltest_reset) configured to control reset in the scan test mode, and a scan reset deactivation signal (ltest_rstdisable) configured to deactivate reset in the scan test mode, to the leading target reset controllers 611 and 612; and a target reset test controller 620 configured to output a target reset test mode signal (TEST_MODE) indicating whether a target is in a test mode and target reset test data (TEST_MODE_RESET) to the leading target reset controllers 611 and 612.

The scan test controller 520 of FIG. 5 and the scan test controller 520 of FIG. 6 may be the same component. The target reset test controller 530 of FIG. 5 and the target reset test controller 620 of FIG. 6 perform the same function, but it is preferable that a separate target reset test controller 530, 620 be disposed for each reset domain.

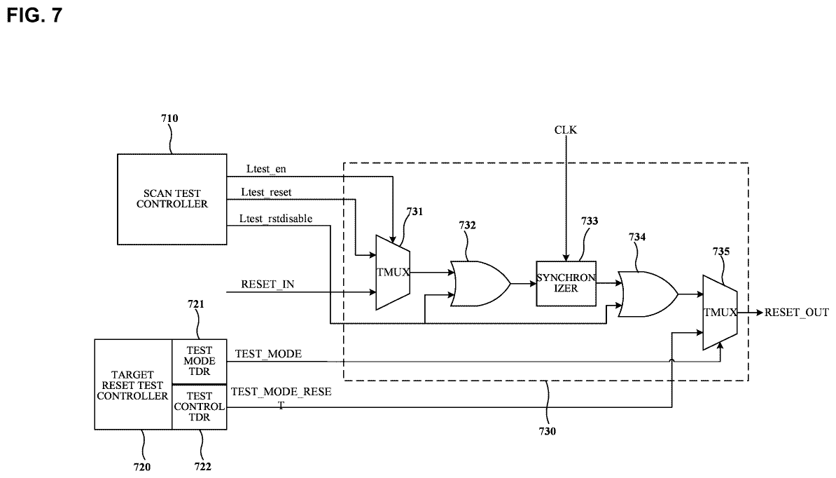

FIG. 7 is a configuration block diagram illustrating a reset test system including a leading target reset controller according to an embodiment of the present disclosure.

The reset test system according to an embodiment of the present disclosure includes: a scan test controller 710 that outputs a scan test enable signal (ltest_en) indicating whether a scan test mode is activated, a scan reset control signal (ltest_reset) for controlling reset in the scan test mode, and a scan reset deactivation signal (ltest_rstdisable) for deactivating reset in the scan test mode; a target reset test controller 720 that outputs a target reset test mode signal (TEST_MODE) indicating whether a target is in a test mode and target reset test data (TEST_MODE_RESET); and a leading target reset controller 730 that outputs the target reset test data (TEST_MODE_RESET) to the target based on the scan test enable signal (ltest_en), the scan reset control signal (ltest_reset), the scan reset deactivation signal (ltest_rstdisable), the target reset test mode signal (TEST_MODE), the target reset test data (TEST_MODE_RESET), and a reset input (RESET_IN), when the reset function is activated in the scan test mode and the target reset test mode is activated.

The leading target reset controller 730 includes a synchronizer 733 that synchronizes the functional reset to the functional clock of the target, and causes the synchronizer 733 to be reset while the reset function is activated in the scan test mode.

The target reset test controller 720 may include: a test mode test data register (TDR) 721 configured to output a target reset test mode signal (TEST_MODE) indicating whether the reset test mode of the target is activated or deactivated; and a test control test data register (TDR) 722 configured to output the target reset test data (TEST_MODE_RESET) when the target is activated in the reset test mode.

The target reset test controller 720 may be a built-in controller based on the IEEE1687 standard. The target reset test controller 720 may configure the test mode TDR 721 and the test control TDR 722 via an internal joint test action group (IJTAG) interface.

The test mode TDR 721 may be configured with a flip-flop and may output the target reset test mode signal (TEST_MODE) indicating activation/deactivation of the reset test mode of the target to the leading target reset controller 730. In other words, the target reset test mode signal (TEST_MODE) may be a 1-bit signal.

The test control TDR 722 may be configured with a flip-flop and may output the target reset test data (TEST_MODE_RESET) to the leading target reset controller 730. The target reset test data (TEST_MODE_RESET) may be a value that determines whether to reset the target while the reset test mode is activated. Accordingly, the target reset test data (TEST_MODE_RESET) may be a 1-bit signal.

The leading target reset controller 730 may include: a first test multiplexer (TMUX) 731 in which the scan reset control signal (ltest_reset) and the reset input (RESET_IN) are input to each input terminal, and the scan test enable signal (ltest_en) is input to a selection terminal and outputs one of the scan reset control signal (ltest_reset) and the reset input (RESET_IN) according to the scan test enable signal (ltest_en); and a first OR operator 732 which performs an OR operation on an output of the first test multiplexer 731 and the scan reset deactivation signal (ltest_rstdisable) and outputs a result to the synchronizer 733. The functional reset may be input from a register as the reset input (RESET_IN).

When the scan test enable signal (ltest_en) is in a scan test activation mode, the first test multiplexer 731 selects and outputs the scan reset control signal (ltest_reset). When the scan test enable signal (ltest_en) is not in the scan test activation mode, the first test multiplexer 731 selects and outputs the reset input (RESET_IN). The first OR operator 732 outputs a ‘high’ signal when at least one of the output of the first test multiplexer 731 and the scan reset deactivation signal (ltest_rstdisable) is ‘high.’

Accordingly, the first test multiplexer 731 and the first OR operator 732 may reset the synchronizer 733 by controlling the scan reset control signal (ltest_reset) when the scan test is activated.

When the scan test is not activated, the reset input (RESET_IN) is provided to the synchronizer 733, and the synchronizer 733 synchronizes the reset input (RESET_IN) with the functional clock (CLK) of the target and outputs the synchronized reset signal.

The leading target reset controller 730 includes: a second OR operator 734 configured to perform an OR operation on the output of the synchronizer 733 and the scan reset disable signal (ltest_rstdisable); and a second test multiplexer 735 configured to receive the output of the second OR operator 734 and the target reset test data (TEST_MODE_RESET) at respective input terminals, and receive the target reset test mode signal (TEST_MODE) at a selection terminal, and output one of the output of the second OR operator 734 and the target reset test data (TEST_MODE_RESET) as a reset output (RESET_OUT) according to the target reset test mode signal (TEST_MODE).

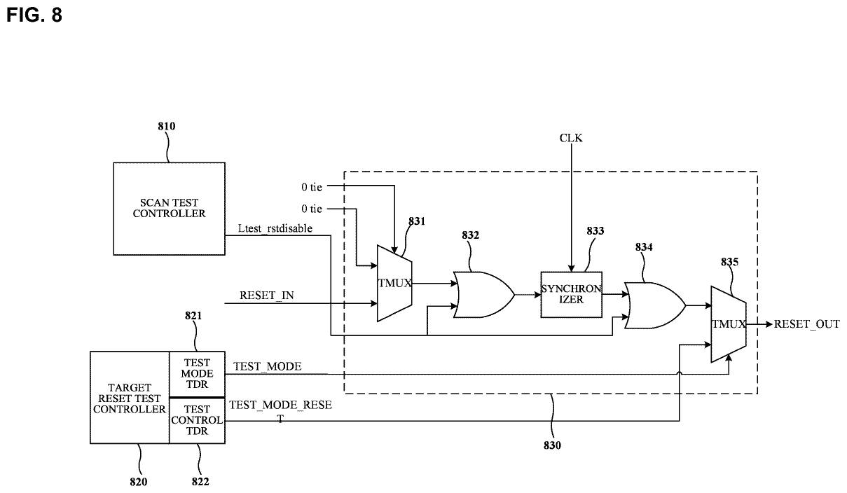

FIG. 8 is a configuration block diagram illustrating a reset test system including a following target reset controller according to an embodiment of the present disclosure.

A scan test controller 810 outputs the scan reset deactivation signal (ltest_rstdisable) to control the reset to be deactivated in the scan test mode to a following target reset controller 830.

The following target reset controller 830 activates the reset function in the scan test mode based on the scan reset deactivation signal (ltest_rstdisable), the target reset test mode signal (TEST_MODE), the target reset test data (TEST_MODE_RESET), and the reset input (RESET_IN) input from a target reset controller located upstream, and outputs the target reset test data (TEST_MODE_RESET) to the target while the target reset test mode is activated. Herein, the upstream target reset controller may be a leading target reset controller or a following target reset controller.

The following target reset controller 830 includes a synchronizer 833 that synchronizes the functional reset to the functional clock of the target, and causes the synchronizer 833 to be reset by the reset input (RESET_IN) while the reset function is activated in the scan test mode.

A target reset test controller 820 may include a test mode test data register (TDR) 821 that outputs the target reset test mode signal (TEST_MODE) indicating whether the reset test mode of the target is activated or deactivated, and a test control test data register (TDR) 822 that outputs the target reset test data (TEST_MODE_RESET) when the target is activated in the reset test mode. The target reset test controller 820, the test mode TDR 821, and the test control TDR (822) of FIG. 8 perform the same functions as the target reset test controller 720, the test mode TDR 721, and the test control TDR 722 of FIG. 7.

The target reset test controller 820 may be a built-in controller based on the IEEE1687 standard. The target reset test controller 820 may configure the test mode TDR 821 and the test control TDR 822 via an IJTAG (Internal Joint Test Action Group) interface.

The test mode TDR 821 may be configured with a flip-flop and may output the target reset test mode signal (TEST_MODE), which indicates whether the reset test mode of the target is activated or deactivated, to the following target reset controller 830. In other words, the target reset test mode signal (TEST_MODE) may be a 1-bit signal.

The test control TDR 822 may be configured with a flip-flop and may output the target reset test data (TEST_MODE_RESET) to the following target reset controller 830. The target reset test data (TEST_MODE_RESET) may be a value that determines whether to reset the target while the reset test mode is activated. Accordingly, the target reset test data (TEST_MODE_RESET) may be a 1-bit signal.

The following target reset controller 830 may include: a first test multiplexer (TMUX) 831, in which a selection terminal and one input terminal are each fixed to a zero level (0 tie), and the reset input (RESET_IN) is input to another input terminal so that the reset input (RESET_IN) is output; and a first OR operator 732 that performs an OR operation on the reset input (RESET_IN) output from the first test multiplexer 831 and the scan reset deactivation signal (ltest_rstdisable), and outputs a result to the synchronizer 833. The reset input (RESET_IN) may be input from the target reset controller at the upstream, which may be either a leading target reset controller or another following target reset controller. The first test multiplexer 831 may output ‘high’ when at least one of the reset input (RESET_IN) or the scan reset deactivation signal (ltest_rstdisable) is ‘high.’

The reset input (RESET_IN) is transmitted from the target reset controller at the upstream, which may be either a leading target reset controller or another following target reset controller. Accordingly, when the scan test is activated, the reset test may be performed while the reset input (RESET_IN) is transmitted along the functional reset path, and the synchronizer 833 may be reset. In addition, the synchronizer 833 outputs the reset input (RESET_IN) by synchronizing the same with the functional clock (CLK) of the target.

The following target reset controller 830 includes: a second OR operator 834 that performs an OR operation on an output of the synchronizer 833 and the scan reset deactivation signal (ltest_rstdisable); and a second test multiplexer 835 in which the output of the second OR operator 834 and the target reset test data (TEST_MODE_RESET) are input to each input terminal, and the target reset test mode signal (TEST_MODE) is input to a selection terminal and outputs one of the output of the second OR operator 834 and the target reset test data (TEST_MODE_RESET) as the reset output (RESET_OUT) according to the target reset test mode signal (TEST_MODE).

In other words, the following target reset controller 830 of FIG. 8 fixes the scan test enable signal (ltest_en) and the scan reset control signal (ltest_reset) of the leading target reset controller 730 of FIG. 7 to zero level so that the first test multiplexer 831 outputs the reset input (RESET_IN) to the first OR operator 732.

The leading target reset controller 730 of FIG. 7 independently and selectively outputs the scan reset control signal (ltest_reset) and the scan input (RESET_IN) based on the scan test enable signal (ltest_en). However, the following target reset controller 830 of FIG. 8 performs the reset by receiving the scan output (RESET_OUT) from an upstream target reset controller as the scan input (RESET_IN), so that the scan reset test can be performed along the functional reset path.

Hereinafter, an operation of the leading target reset controller 730 according to an embodiment of the present disclosure will be described.

In the functional mode of the system-on-chip device, the first test multiplexer 731 outputs the reset input (RESET_IN), and the first OR operator 732 performs a logical OR operation on the reset input (RESET_IN) and the scan reset deactivation signal (ltest_rstdisable), and transmits the result to the synchronizer 733. The synchronizer 733 synchronizes the reset input (RESET_IN) with the functional clock (CLK) of the target and outputs the synchronized signal, which is output to the target via the second OR operator 734 and the second test multiplexer 735.

The reset control of the system-on-chip device may be classified into reset control in a functional mode and reset control in a test mode. The reset control in the test mode may include control of a reset signal in a general test mode and in a scan test mode. Further, the scan test mode may be classified into a scan capture mode, in which the scan reset control signal (ltest_reset) is toggled between ‘low’ and ‘high,’ and a scan shift mode, in which the scan reset control signal (ltest_reset) is held at ‘high.’

When the reset signal needs to be controlled in the functional mode, the scan test enable signal (ltest_en), the scan reset deactivation signal (ltest_rstdisable), and the target reset test mode (TEST_MODE) are all set to ‘low,’ and the reset input (RESET_IN) passes through the synchronizer 733 and is output as a reset output (RESET_OUT) synchronized with the functional clock (CLK). The reset output (RESET_OUT) is provided to the target and the downstream target reset controller.

In a general test mode, when the reset signal needs to be controlled, the scan test enable signal (ltest_en) and the scan reset deactivation signal (Itest_rstdisable) are set to ‘low,’ and the target reset test mode (TEST_MODE) is set to ‘high.’ Then, the target reset test data (TEST_MODE_RESET) is output as the reset output (RESET_OUT) from the second test multiplexer 735. The reset output (RESET_OUT) is provided to the target and the downstream following target reset controller.

In the scan test mode, when the scan reset control signal (ltest_reset) needs to be controlled, the scan test enable signal (ltest_en) is set to ‘high,’ the scan reset deactivation signal (ltest_rstdisable) is set to ‘low,’ and the target reset test mode (TEST_MODE) is set to ‘low.’ In this case, the first test multiplexer 731 and the first OR operator 732 select the scan reset control signal (ltest_reset) and output it to the synchronizer 733. The synchronizer 733 outputs the scan reset control signal (ltest_reset), and the second test multiplexer 735 outputs the scan reset control signal (ltest_reset) as the reset output (RESET_OUT).

When the scan reset signal needs to be fixed to ‘high,’ the scan test enable signal (ltest_en) is set to ‘high,’ the scan reset deactivation signal (ltest_rstdisable) is set to ‘high,’ and the target reset test mode (TEST_MODE) is set to ‘low.’ In this case, the first OR operator 732 and the second OR operator 734 may constantly output a high-level signal to fix the scan reset signal to ‘high.’

The operation of the following target reset controller 830 is described. In the functional mode of the system-on-chip device, the first test multiplexer 831 outputs the reset input (RESET_IN), and the first OR operator 832 performs an OR operation on the reset input (RESET_IN) and the scan reset deactivation signal (ltest_rstdisable) and transmits the result to the synchronizer 833. Since the scan reset deactivation signal (ltest_rstdisable) is ‘low’ in the functional mode, the first OR operator 832 outputs the reset input (RESET_IN) to the synchronizer 833. When the reset input (RESET_IN) is ‘high,’ the synchronizer 833 synchronizes the reset input (RESET_IN) with the functional clock (CLK) of the target and outputs it, and the reset output (RESET_OUT) is transmitted to the target through the second OR operator 834 and the second test multiplexer 835.

When the reset signal needs to be controlled in the general test mode, the scan reset deactivation signal (ltest_rstdisable) becomes ‘low,’ the target reset test mode (TEST_MODE) becomes ‘high,’ and the target reset test data (TEST_MODE_RESET) is output as the reset output (RESET_OUT) from the second test multiplexer 835.

In the scan test mode, when the scan reset control signal (ltest_reset) needs to be controlled, the scan reset deactivation signal (ltest_rstdisable) becomes ‘low,’ and the target reset test mode (TEST_MODE) becomes ‘low.’ The synchronizer 833 outputs the reset input (RESET_IN), and the second test multiplexer 835 also outputs the reset input (RESET_IN) as the reset output (RESET_OUT). In this case, since the scan reset control signal (ltest_reset) is output from the leading target reset controller at an upstream side, the following scan reset controller also outputs the scan control signal as a result.

In the case where the scan reset signal needs to be fixed to ‘high,’ the reset input (RESET_IN) is input as ‘high,’ the scan reset deactivation signal (ltest_rstdisable) becomes ‘high,’ and the target reset test mode (TEST_MODE) becomes ‘low.’ In this case, the first OR operator 832 and the second OR operator 834 always output 1, thereby fixing the scan reset signal to ‘high.’

In the reset test system of FIG. 5, all the following target reset controllers may be configured as the leading target reset controller of FIG. 7. However, in such a case, since each leading target reset controller independently and selectively outputs the scan reset control signal (ltest_reset) and the scan input (RESET_IN) based on the scan test enable signal (ltest_en), the reset connection between the two target reset controllers is excluded from the test coverage.

However, in the present disclosure, a leading target reset controller is disposed at the most upstream end, and a following target reset controller is disposed downstream in a chain connection to the leading target reset controller, and since the following target reset controller receives a scan output of the preceding stage as a scan input and performs a reset, it becomes possible to test the reset connection between the two target reset controllers.

It should be understood that many variations and modifications may be made to the embodiments described above, and each of the elements thereof should be understood as one of other allowable examples. All such modifications and variations are intended to be included within the scope of the present disclosure and to be protected by the following claims. The embodiments of the present disclosure described above may be implemented as program instructions executable by various computer components, and may be recorded on a computer-readable recording medium. The computer-readable recording medium may include program instructions, data files, and data structures alone or in combination. The program instructions recorded on the computer-readable recording medium may be specially designed and constructed for the present disclosure, or may be known and usable by those skilled in the art of computer software. Examples of the computer-readable recording medium include magnetic media such as hard disks, floppy disks, and magnetic tapes; optical recording media such as CD-ROMs and DVDs; magneto-optical media such as floptical disks; and hardware devices specially configured to store and execute program instructions such as ROM, RAM, and flash memory. Examples of the program instructions include both machine language code generated by a compiler and high-level language code that can be executed by a computer using an interpreter. The hardware device may be configured to operate as one or more software modules to perform processing according to the present disclosure, and vice versa.

While the present disclosure has been described with reference to specific elements, limited exemplary embodiments, and drawings, these are provided solely for better understanding of the present disclosure and are not intended to limit the scope thereof. Those skilled in the art to which the present disclosure pertains may devise various modifications and alterations based on the above description.

The spirit of the present disclosure is defined by the appended claims rather than by the description preceding them, and all changes and modifications that fall within metes and bounds of the claims, or equivalents of such metes and bounds are therefore intended to be embraced by the range of the spirit of the present disclosure.

### DETAILED DESCRIPTION OF MAIN ELEMENTS

511, 512, 611, 612, 730: leading target reset controller
513, 514, 830: following target reset controller
520, 710, 810: scan test controller
530, 620, 720, 820: target reset test controller
731, 831: first test multiplexer
732, 832: first OR operator
733, 833: synchronizer
734, 834: second OR operator
735, 835: second test multiplexer
721, 821: test mode TDR
722, 822: test control TDR

What is claimed is:

1. A reset test system comprising:
a scan test controller configured to generate a scan test enable signal (ltest_en) indicating whether a scan test mode is activated, a scan reset control signal (ltest_reset) configured to control a reset in the scan test mode, and a scan reset deactivation signal (ltest_rstdisable) configured to deactivate the reset in the scan test mode;
a target reset test controller configured to generate a target reset test mode signal (TEST_MODE) indicating whether a target is in a test mode and target reset test data (TEST_MODE_RESET);
a leading target reset controller configured to receive the scan test enable signal (ltest_en), the scan reset control signal (ltest_reset), the scan reset deactivation signal (ltest_rstdisable), the target reset test mode signal (TEST_MODE), the target reset test data (TEST_MODE_RESET), and a leading reset input, configured to synchronize the leading reset input to a functional clock of the target and output the synchronized signal as a leading reset output in a functional mode, and configured to output the target reset test data (TEST_MODE_RESET) as the leading reset output when the reset is activated in the scan test mode; and
a following target reset controller configured to receive the scan reset deactivation signal (ltest_rstdisable), the target reset test mode signal (TEST_MODE), the target reset test data (TEST_MODE_RESET), and the leading reset output as a following reset input, configured to synchronize the following reset input to the functional clock of the target and output the synchronized signal as a following reset output in the functional mode, and configured to output the target reset test data (TEST_MODE_RESET) as the following reset output when the reset is activated in the scan test mode.

2. The reset test system of claim 1, wherein:
the leading target reset controller comprises a leading synchronizer configured to synchronize the leading reset input to a functional clock of the target;
the following target reset controller comprises a following synchronizer configured to synchronize the following reset input to the functional clock of the target; and
the leading synchronizer and the following synchronizer are configured to be reset when the reset is activated in the scan test mode.

3. The reset test system of claim 1, wherein the target reset test controller is a built-in controller based on the IEEE1687 standard.

4. The reset test system of claim 1, wherein the target reset test controller is disposed in correspondence with each reset domain.

5. The reset test system of claim 1, wherein the target reset test controller comprises:
a test mode test data register (TDR) configured to output the target reset test mode signal (TEST_MODE) indicating whether a reset test mode of the target is activated or deactivated; and
a test control test data register (TDR) configured to output the target reset test data (TEST_MODE_RESET) in response to the activation of the reset test mode of the target.

6. The reset test system of claim 5, wherein the test mode test data register (TDR) and the test control test data register (TDR) are configured via an Internal Joint Test Action Group (IJTAG) interface.

7. The reset test system of claim 2, wherein the leading target reset controller comprises:
a first test multiplexer in which the scan reset control signal (ltest_reset) and the leading reset input are input to each input terminal, and the scan test enable signal (ltest_en) is input to a selection terminal and outputs one of the scan reset control signal (ltest_reset) and the leading reset input according to the scan test enable signal (ltest_en); and
a first OR operator that performs an OR operation on an output of the first test multiplexer and the scan reset deactivation signal (ltest_rstdisable) and outputs a result to the leading synchronizer.

8. The reset test system of claim 7, wherein the leading target reset controller further comprises:
a second OR operator that performs an OR operation on an output of the leading synchronizer and the scan reset deactivation signal (ltest_rstdisable); and
a second test multiplexer in which an output of the second OR operator and the target reset test data (TEST_MODE_RESET) are input to each input terminal, and the target reset test mode signal (TEST_MODE) is input to the selection terminal and outputs one of the output of the second OR operator and the target reset test data (TEST_MODE_RESET) according to the target reset test mode signal (TEST_MODE).

9. The reset test system of claim 2, wherein the following target reset controller comprises:
a first test multiplexer in which a selection terminal and one input terminal are each fixed to a zero level, and the leading reset input is input to another input terminal to output the leading reset input; and
a first OR operator that performs an OR operation on the leading reset input output from the first test multiplexer and the scan reset deactivation signal (ltest_rstdisable) and outputs a result to the following synchronizer.

10. The reset test system of claim 9, wherein the following target reset controller further comprises:
a second OR operator that performs an OR operation on an output of the following synchronizer and the scan reset deactivation signal (ltest_rstdisable); and
a second test multiplexer in which an output of the second OR operator and the target reset test data (TEST_MODE_RESET) are input to each input terminal, and the target reset test mode signal (TEST_MODE) is input to the selection terminal and outputs one of the output of the second OR operator and the target reset test data (TEST_MODE_RESET) according to the target reset test mode signal (TEST_MODE).

11. A system-on-chip comprising a reset test system, wherein the reset test system comprises:
a scan test controller configured to generate a scan test enable signal (ltest_en) indicating whether a scan test mode is activated, a scan reset control signal (ltest_reset) configured to control a reset in the scan test mode, and a scan reset deactivation signal (Itest_rstdisable) configured to deactivate the reset in the scan test mode;
a target reset test controller configured to generate a target reset test mode signal (TEST_MODE) indicating whether a target is in a test mode and target reset test data (TEST_MODE_RESET);
a leading target reset controller configured to receive the scan test enable signal (ltest_en), the scan reset control signal (ltest_reset), the scan reset deactivation signal (ltest_rstdisable), the target reset test mode signal (TEST_MODE), the target reset test data (TEST_MODE_RESET), and a leading reset input, configured to synchronize the leading reset input to a functional clock of the target and output the synchronized signal as a leading reset output in a functional mode, and configured to output the target reset test data (TEST_MODE_RESET) as the leading reset output when the reset is activated in the scan test mode; and
a following target reset controller configured to receive the scan reset deactivation signal (ltest_rstdisable), the target reset test mode signal (TEST_MODE), the target reset test data (TEST_MODE_RESET), and the leading reset output as a following reset input, configured to synchronize the following reset input to the functional clock of the target and output the synchronized signal as a following reset output in the functional mode, and configured to output the target reset test data (TEST_MODE_RESET) as the following reset output when the reset is activated in the scan test mode.

12. The system-on-chip of claim 11, wherein:
the leading target reset controller comprises a leading synchronizer configured to synchronize the leading reset input to a functional clock of the target;
the following target reset controller comprises a following synchronizer configured to synchronize the following reset input to the functional clock of the target; and
the leading synchronizer and the following synchronizer are configured to be reset when the reset is activated in the scan test mode.

13. The system-on-chip of claim 11, wherein the target reset test controller is a built-in controller based on the IEEE1687 standard.

14. The system-on-chip of claim 11, wherein the target reset test controller is disposed in correspondence with each reset domain.

15. The system-on-chip of claim 11, wherein the target reset test controller comprises:
a test mode test data register (TDR) configured to output the target reset test mode signal (TEST_MODE) indicating whether a reset test mode of the target is activated or deactivated; and
a test control test data register (TDR) configured to output the target reset test data (TEST_MODE_RESET) in response to the activation of the reset test mode of the target.

16. The system-on-chip of claim 15, wherein the test mode test data register (TDR) and the test control test data register (TDR) are configured via an Internal Joint Test Action Group (IJTAG) interface.

17. The system-on-chip of claim 12, wherein the leading target reset controller comprises:
a first test multiplexer in which the scan reset control signal (ltest_reset) and the leading reset input are input to each input terminal, and the scan test enable signal (ltest_en) is input to a selection terminal and outputs one of the scan reset control signal (ltest_reset) and the leading reset input according to the scan test enable signal (ltest_en); and
a first OR operator that performs an OR operation on an output of the first test multiplexer and the scan reset deactivation signal (ltest_rstdisable) and outputs a result to the leading synchronizer.

18. The system-on-chip of claim 17, wherein the leading target reset controller further comprises:
a second OR operator that performs an OR operation on an output of the leading synchronizer and the scan reset deactivation signal (ltest_rstdisable); and
a second test multiplexer in which an output of the second OR operator and the target reset test data (TEST_MODE_RESET) are input to each input terminal, and the target reset test mode signal (TEST_MODE) is input to the selection terminal and outputs one of the output of the second OR operator and the target reset test data (TEST_MODE_RESET) according to the target reset test mode signal (TEST_MODE).

19. The system-on-chip of claim 12, wherein the following target reset controller comprises:
a first test multiplexer in which a selection terminal and one input terminal are each fixed to a zero level, and the leading reset input is input to another input terminal to output the leading reset input; and
a first OR operator that performs an OR operation on the leading reset input output from the first test multiplexer and the scan reset deactivation signal (ltest_rstdisable) and outputs a result to the following synchronizer.

20. The system-on-chip of claim 19, wherein the following target reset controller further comprises:
a second OR operator that performs an OR operation on an output of the following synchronizer and the scan reset deactivation signal (ltest_rstdisable); and
a second test multiplexer in which an output of the second OR operator and the target reset test data (TEST_MODE_RESET) are input to each input terminal, and the target reset test mode signal (TEST_MODE) is input to the selection terminal and outputs one of the output of the second OR operator and the target reset test data (TEST_MODE_RESET) according to the target reset test mode signal (TEST_MODE).
